(19) United States
(12) Patent Application Publication
(10) Pub. No.: US 2004/0032780 A1
(43) Pub. Date: Feb. 19, 2004

(54) System and method for generating a clock signal in a communication system

(76) Inventors: Ehud Langberg, Wayside, NJ (US); Laurent Alloin, Monmouth Beach, NJ (US); Peter Kleewein, Eatontown, NJ (US); Jean-Francois Lopez, Eatontown, NJ (US); Shareq Rahman, Morganville, NJ (US); Patrick Duvaut, Tinton Falls, NJ (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/408,615

(22) Filed: Apr. 7, 2003

Related U.S. Application Data
(63) Continuation-in-part of application No. 10/315,743, filed on Dec. 10, 2002.
(60) Provisional application No. 60/371,006, filed on Apr. 8, 2002.

(51) Int. Cl. G11C 7/00

(52) U.S. Cl. 365/222

(57) ABSTRACT

Approaches to generating clock signals are presented in which a signal is received from a line and a clock signal is generated as a function of the received signal. The received signal has portions that are correlated to a cyclostationary disturbance that is present on the line. Hence, by setting the rising edge and the falling edge of the clock as a function of the received signal may result in a clock signal that is substantially synchronous to the cyclostationary signal on the line.

### CROSS REFERENCE TO RELATED APPLICATIONS

This application claims the benefit of U.S. provisional patent application Serial No. 60/371,006, filed Apr. 8, 2002, which is incorporated herein by reference in its entirety.

### FIELD OF THE INVENTION

The present disclosure relates generally to communication systems and, more particularly, to systems and methods for generating clock signals in communication systems.

### BACKGROUND

High-speed Internet services are becoming more popular as Internet users are accessing more complex applications over the Internet. These high-speed services include Digital Subscriber Lines (DSL), cable modems, Integrated Services Digital Networks (ISDN), TI lines, satellite networks, etc.

If two services are deployed on non-overlapping communication channels, then there is little concern that one service will disrupt the other service. For example, there is little concern that DSL services will interfere with satellite services because DSL is deployed on a two-conductor pair wire while satellite services are provided over a wireless connection.

Conversely, if two services are deployed on the same communication channel in non-overlapping bandwidths, then various methods are often employed to reduce disruptions of one service onto another. For example, in Annex C systems, where DSL and ISDN services are concurrently deployed on the same line in overlapping bandwidths, the DSL service may corrupt the ISDN service to a certain extent, and vice versa, within that overlapping bandwidth. This corruption results from cross-talk between DSL and ISDN. Since the ISDN service are governed by an ISDN. clock, the transmit and receive periods of the ISDN service exhibit cyclostationary behavior. This cyclostationary behavior of ISDN imposes itself as a cyclical disturbance onto the overlapping bandwidth of concurrently-deployed DSL services.

To minimize such disturbances, methods have been proposed in which DSL services are synchronized to the ISDN clock such that the DSL services and the ISDN services impose minimal disturbances on each other. In order for ISDN services and DSL services to be synchronized to each other, the ISDN clock signal must typically be provided to the DSL service because DSL services are typically not governed by the ISDN clock. Normally, the ISDN clock signal is provided by the TELCO at a cost to the DSL service provider or the DSL service subscriber. This added expense gives rise to a need in the industry for alternative approaches to synchronizing DSL services to ISDN services.

### SUMMARY

The present disclosure provides systems and methods for generating clock signals in communication systems.

Briefly described, in architecture, one embodiment of the system comprises a receiver and logic components. The receiver is adapted to receive a signal from a line.

The signal has a first period and a second period, which are correlated to an active period and an inactive period of disturbances in the signal. The logic components are adapted to set a rising edge of a clock signal and a falling edge of the clock signal. The rising edge and the falling edge correspond to an onset of the active period and the onset of the inactive period, respectively.

The present disclosure also provides methods for generating clock signals in communication systems.

In this regard, one embodiment of the method comprises the steps of receiving a signal from a line and setting a rising edge and a falling edge of a clock signal in response to the received signal. The received signal has a first period and a second period that are correlated to an active and inactive period of disturbances to the signal. The rising edge of the clock signal is set to correspond to an onset of the active period, while the falling edge of the clock signal is set to correspond to an onset of the inactive period.

Other systems, methods, features, and advantages will be or become apparent to one with skill in the art upon examination of the following drawings and detailed description. It is intended that all such additional systems, methods, features, and advantages be included within this description.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a block diagram showing a non-limiting example of a digital communication system as an asymmetric Digital Subscriber Line (ADSL) system.

FIG. 2 is a block diagram showing the ADSL modem of FIG. 1 in greater detail.

FIG. 3 is a block diagram showing the encoder and gain scaler of FIG. 2 in greater detail.

FIGS. 4 through 6 are flowcharts showing embodiments of a method for generating a clock signal.

FIG. 7 is an example timing diagram showing an example embodiment in which cyclostationary disturbances are generated by concurrent deployment of integrated services digital network (ISDN) and ADSL.

### DETAILED DESCRIPTION OF THE PREFERRED EMBODIMENTS

Reference is now made in detail to the description of the embodiments as illustrated in the drawings. While several embodiments are described in connection with these drawings, there is no intent to limit the invention to the embodiment or embodiments disclosed herein. On the contrary, the intent is to cover all alternatives, modifications, and equivalents.

The several embodiments described below permit recovery of a time-compression modulated (TCM) Integrated Services Digital Network (ISDN) clock signal from the line without receiving the clock signal from a provider. In this regard, Digital Subscriber Line (DSL) services may be synchronized with TCM-ISDN services without the added cost of paying a TELCO for a TCM-ISDN clock signal. In a general sense, the several embodiments may be seen as teaching systems and methods for generating a clock signal in the presence of any type of cyclostationary noise or disturbance, where the cyclostationary disturbance has a relatively fixed periodicity. In this regard the TCM-ISDN transmit period and the TCM-ISDN receive period may be seen as periods that define the behavior of a particular cyclostationary disturbance.

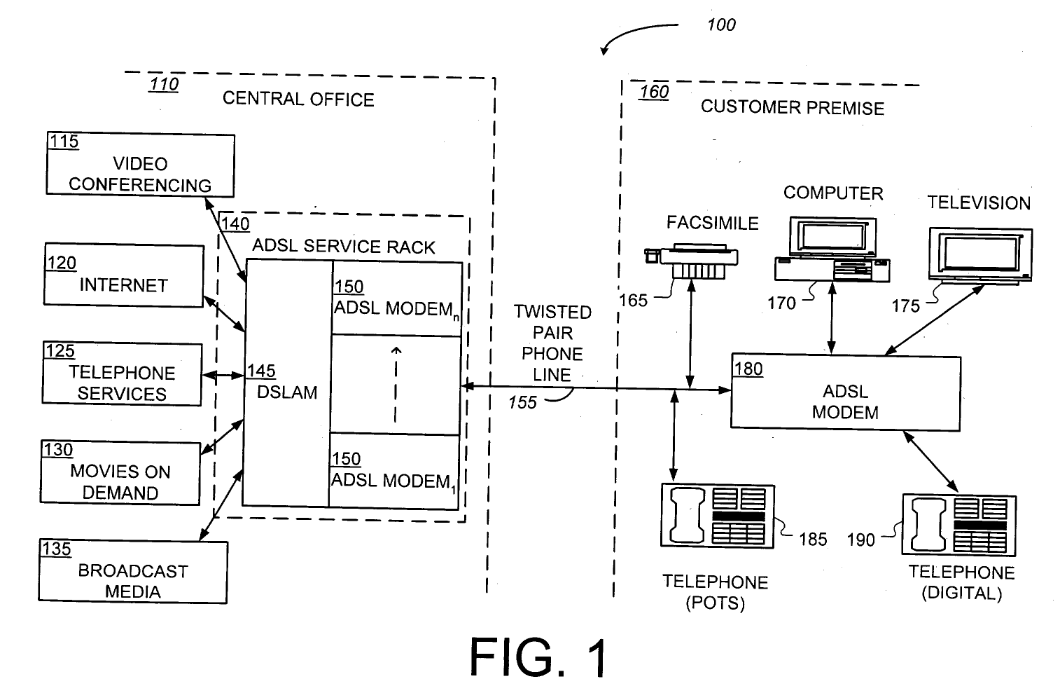

FIG. 1 is a block diagram showing a non-limiting example of a digital communication system as an asymmetric Digital Subscriber Line (ADSL) system 100. In this non-limiting example environment, a central office 110 is connected to a customer premises 160 via a two-conductor pair wire 155. On the side of the central office 110 an ADSL service rack 140 gathers information for transmission. The information may be in the form of video conferencing 115, Internet 120, telephone services 125, movies on demand 130, or broadcast media 135. All of the information is gathered at a Digital Subscriber Line access multiplexer (DSLAM) 145, which assembles the data for transmission by ADSL modems 150. Once the information has been coded and framed, it is sent to the customer premises 160 via a local loop, generally a two-conductor pair 155. The data is received at the customer premises 160 by an ADSL modem 180. The information is then decoded and provided to the user. Several non-limiting examples of communication services that use the decoded information include a fax 165, a user's computer 170, a television set 175, an analog telephone 185, or, in the alternative, a digital telephone 195.

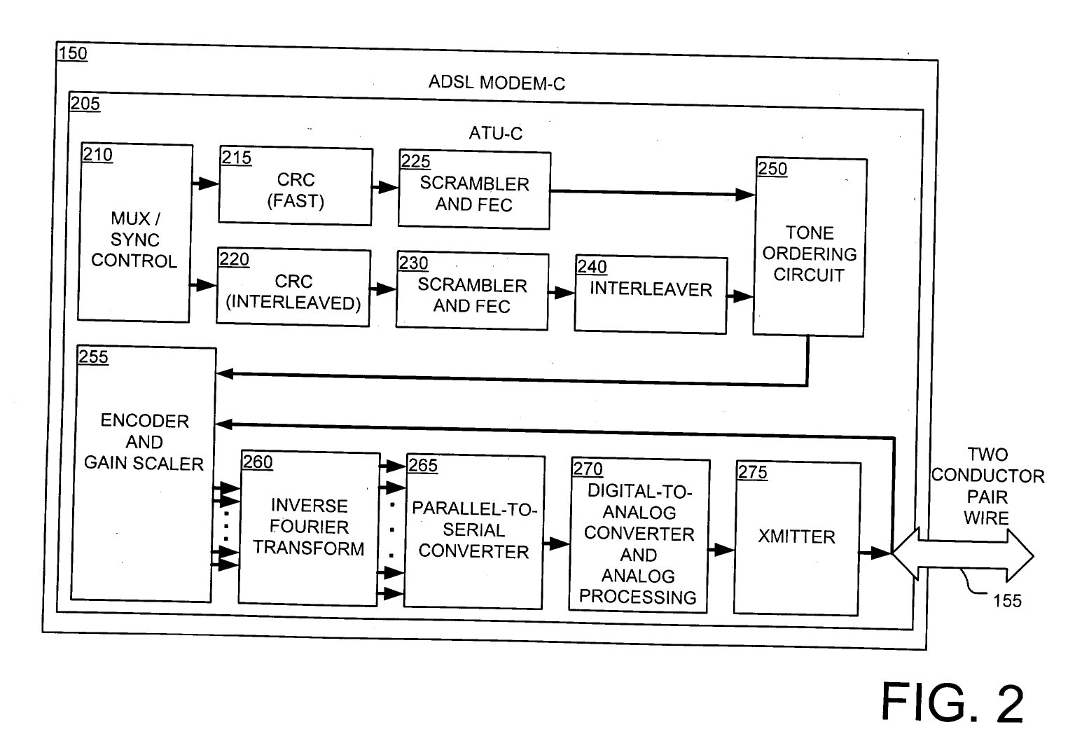

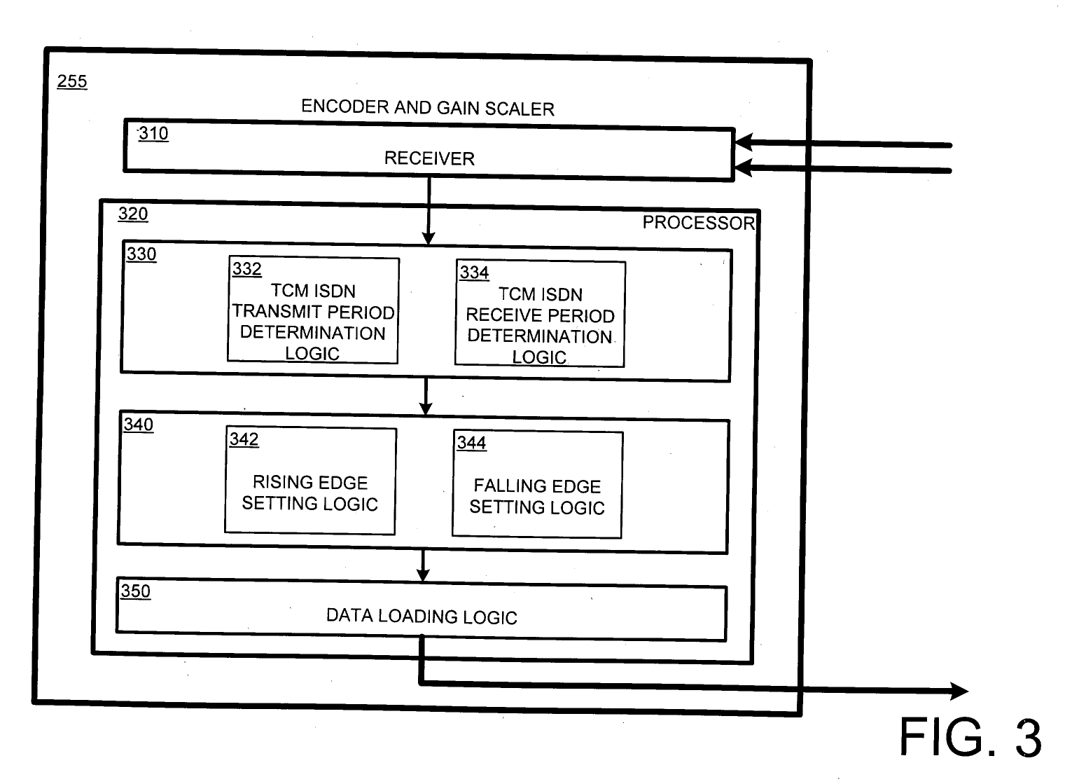

FIG. 2 is a block diagram showing the ADSL modem 150 of FIG. 1 in greater detail. While FIG. 2 shows only one ADSL modem 150, it should be appreciated that each of the ADSL modems 150 of FIG. 2 may have similar components. As shown in FIG. 2, the ADSL modem 150 at the central office 110 comprises an ADSL transceiver unit (ATU-C) 205 configured to assemble data for transmission on the communication line 155. In this regard, the ATU-C 205 comprises both a fast path and an interleaved path between a multiplexer (MUX) and synchronization (sync) control block 210 and a tone ordering circuit 250. The fast path, which provides low latency, comprises a fast cyclic redundancy checking (CRC) block 215 and a scrambling and forward error correcting (FEC) block 225. The interleaved path, which provides a lower error rate at a greater latency, comprises an interleaved CRC block 220, a scrambling and FEC block 230, and an interleaver 240. Since MUX/sync control blocks 210, CRC blocks 215, 220, scrambling and FEC blocks 225, 230, interleavers 240, and tone ordering circuits 250 are known to those of ordinary skill in the art, further discussion of these components is omitted here. However, it should be appreciated that the signal, upon traversing either the fast path or the interleaved path, enters an encoding and gain scaling block 255, which encodes the data into a constellation and also scales the data for transmission. The encoding and gain scaling block 255 is discussed in greater detail with reference to FIG. 3.

Once the data has been encoded and gain-scaled, the data is relayed in parallel blocks to an inverse Fourier transform (IFT) block 260, which performs a IFT on the parallel data blocks. The IFT data is conveyed to a parallel-to-serial (P/S) converter 265, which converts the data into a serial data stream. The serial data stream is conveyed to a digital-to-analog (D/A) converter and analog processor 270, which produces an analog signal for data transmission. Since IFT blocks 250, P/S converters 255, D/A converters and analog processors 270 are known to those of ordinary skill in the art, further discussion of these components is omitted here. The analog signal is transmitted through the communication line 155 by a transmitter 275 in the ATU-C 205.

FIG. 3 is a block diagram showing the encoder and gain scaler 255 of FIG. 2 in greater detail. As shown in FIG. 3, the encoder and gain scaler 255 comprises a receiver 310 and a processor 320. In an example embodiment, the receiver 310 and the processor 320 are part of a DSL system employing discrete multi-tone (DMT) modulation. Additionally, if the DSL-DMT system is governed by cyclostationary interferences from concurrently deployed systems, such as TCM-ISDN, then the DSL system may also be capable of dual-modulation tuning (e.g., dual bit-mapping). Since dual bit-mapping techniques are known to those of ordinary skill in the art, further discussion of dual bit-mapping techniques is omitted here. In any event, in the example embodiment, the receiver 310 receives data from the tone-ordering circuit 250 as well as signals from the communication line 155. Since upstream and downstream signals are impacted by the cyclostationary nature of the TCM-ISDN interferences, it is desirable to synchronize the transmission and reception of DSL signals with the TCM-ISDN interferences using, for example, known dual bit-mapping techniques.

In the absence of a TCM-ISDN clock signal, which normally indicates whether or not self-disturbance is present in the system, by indicating whether or not the TCM-ISDN service is transmitting or receiving, the synchronization between DSL and TCM-ISDN would be provided using an alternative approach. Since the signals from the communication line 155 are typically updated for each data frame being encoded and gain scaled, the encoder/gain scaler 255 is continuously updated with line information. If a cyclostationary interference, such as that exhibited by TCM-ISDN, is present, then that cyclostationary interference manifests itself in the line information. Hence, the line information may be used to generate a clock signal that is substantially synchronous to the cyclostationary interference.

The processor 320 of FIG. 3 is adapted to extract this information from the line 155 and to generate a clock signal using the extracted information. Thus, in architecture, the processor 320 may have two broad sets of logic components: the first set 330 being configured to determine the periodicity of the cyclostationary noise, and the second set 340 being configured to set the rising and falling edges of the clock signal. The edge-setting logic components 340 generate a signal that drives a clock-generating circuit such as a phase-locked loop (PLL) circuit. In the context of TCM-ISDN interferences, the first set 330 of logic components comprise TCM-ISDN transmitting-period-determination logic 332 and TCM-ISDN receiving-period-determination logic 334. Similarly, the second set 340 of logic components comprise rising-edge-setting logic 342 and falling-edge-setting logic 344.

Thus, in operation, the receiver 310 receives a signal from the line 155, which is characterized by a signal-to-noise ratio (SNR), line attenuation information, and other known characteristics. Since these characteristics are affected by the different cycles (i.e., transmit or receive) of concurrently deployed TCM-ISDN services, these signal characteristics arc reflective of whether the TCM-ISDN service is transmitting or receiving.

The received signal is conveyed to the first set 330 of logic components in the processor 320 at which point the TCM-ISDN transmitting-period-determination logic 332 determines the time periods in which the TCM-ISDN service is transmitting signals. Similarly, the TCM-ISDN receiving-period-determination logic 334 determines the time periods in which the TCM-ISDN service is receiving signals. Alternatively, the TCM-ISDN receiving period may be presumed to be the non-transmitting period. In this regard, the TCM-ISDN receiving-period-determination logic 334 may be wholly removed from the system without adverse effect to the invention. In any event, once the first set 330 of logic components determines the onset of the transmitting period and the onset of the receiving period, this information is conveyed to the second set 340 of logic components.

The second set 340 of logic components receives this information and, using this information, the rising-edge-setting logic 342 generates a signal at the onset of the TCM-ISDN transmission period. The generated signal is used to drive the rising edge of a clock. Similarly, using the information indicative of the onset of the TCM-ISDN receiving period, the falling-edge-setting logic 344 generates a signal that is used to drive the falling edge of the clock. As shown in FIG. 3, the system, therefore, generates a clock signal that is substantially synchronous with the TCM-ISDN interferences without the need for a separate TCM-ISDN clock signal. While one embodiment describes the transmitting of data during the TCM-ISDN transmit period, it should be appreciated that, in other embodiments, data may be transmitted during the TCM-ISDN receive period. Similarly, while one embodiment shows the receiving of data during the TCM-ISDN receive period, data may be received during the TCM-ISDN transmit period in other embodiments. Once the DSL system is substantially synchronized to the TCM-ISDN interferences, the data may be loaded by the data-loading logic 350 using a dual bit-mapping scheme or other technique that accounts for such a cyclostationary interference.

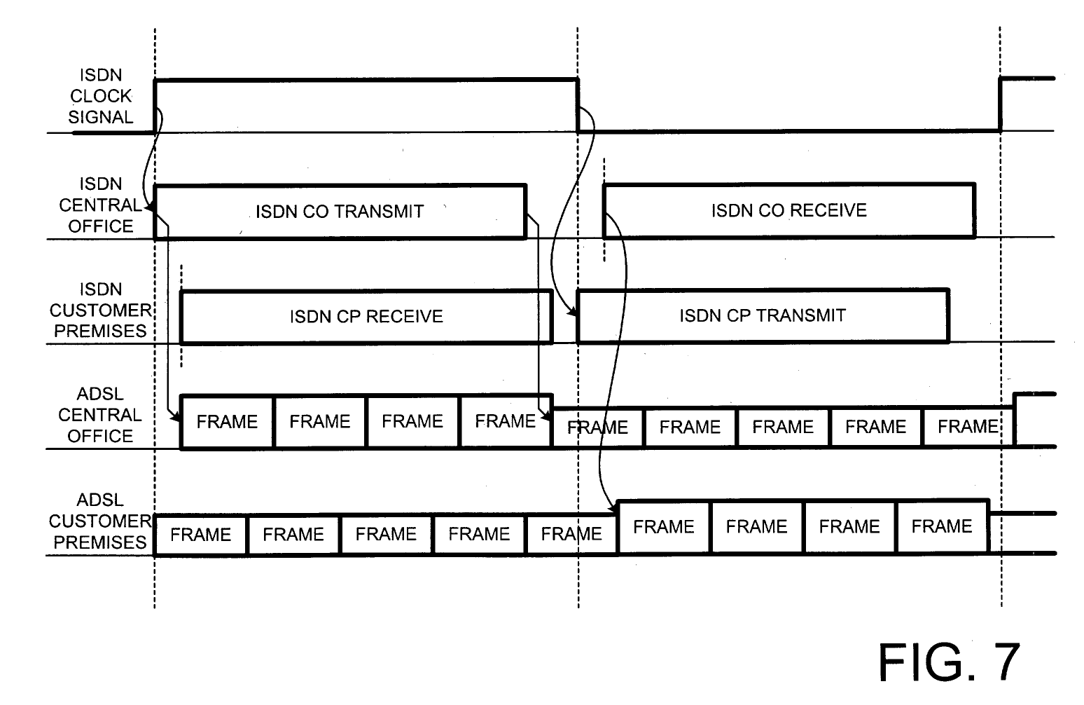

As shown in FIGS. 1 through 3, the DSL service may be synchronized to the TCM-ISDN service without directly providing a TCM-ISDN clock signal to the DSL system 100. An example timing diagram is provided in FIG. 7 and described in detail below.

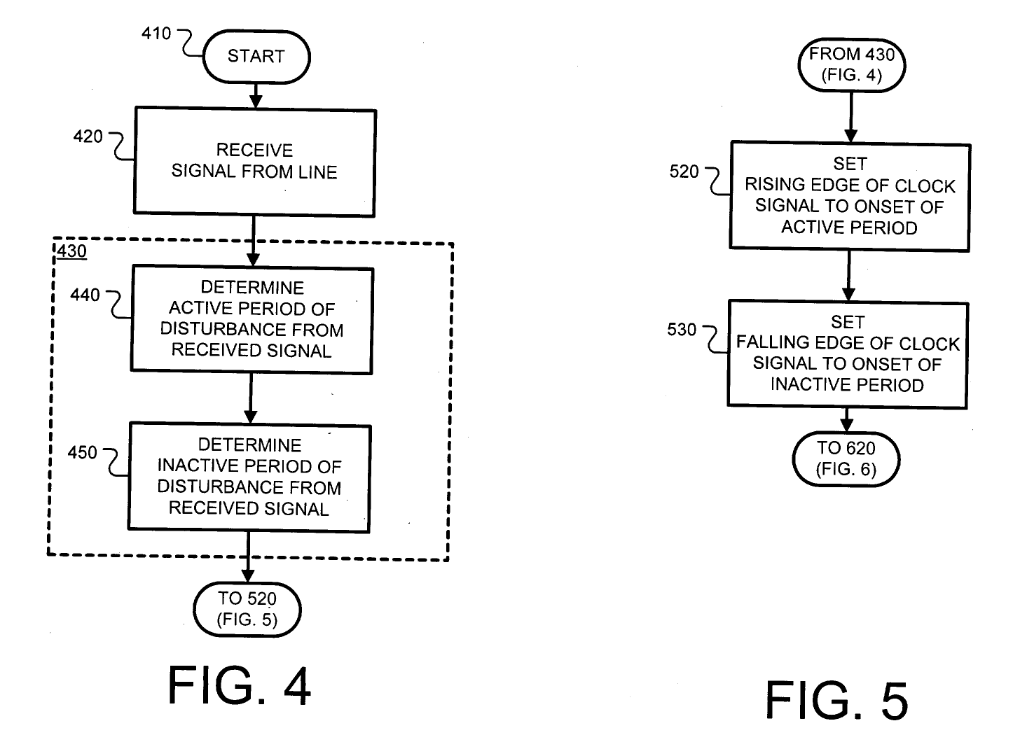

Having described several embodiments of systems configured to generate a clock signal, attention is turned to FIGS. 4 through 6, which are flowcharts showing embodiments of methods that may be implemented by the systems of FIGS. 1 through 3. It should, however, be appreciated that the embodiments of the methods of FIGS. 4 through 6 are not necessarily limited to the systems of FIGS. 1 through 3. Rather, the embodiments of the methods may be implemented in any system exhibiting cyclostationary disturbances.

As shown in FIG. 4, one embodiment of the method begins with the step of receiving (420) a signal from a line. The signal is characterized by a cyclostationary disturbance having a first period and a second period. The first period is designated as an active period in which the disturbance is relatively large, while the second period is designated as an inactive period in which the disturbance is relatively small. Upon receiving (420) the signal, the periodicity of the cyclostationary disturbance is determined (430). The determining (430) of the periodicity may be seen as comprising the steps of determining (440) the active period of the disturbance of the signal, and determining (450) the inactive period of the disturbance of the signal. In the context of TCM-ISDN, the active period may be seen as the transmitting period of TCM-ISDN and the inactive period may be seen as the receiving period of TCM-ISDN. In other embodiments, the inactive period may be seen as the transmitting period of TCM-ISDN while the active period may be seen as the receiving period of TCM-ISDN. In either event, once these periods have been determined (430, 440, 450), the process continues to FIG. 5.

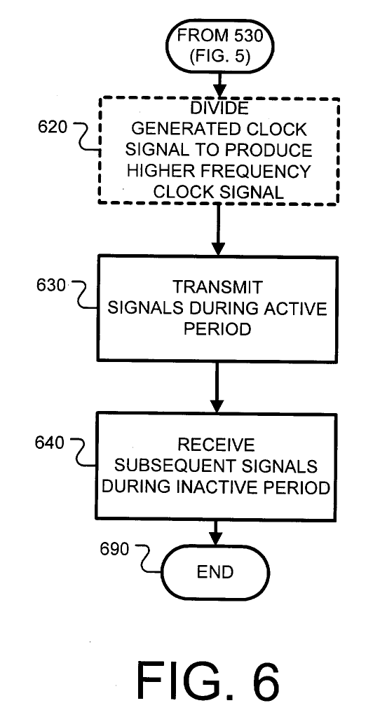

As shown in FIG. 5, a rising edge of a clock is set (520) to correspond to the onset of the active period. Thus, in the context of TCM-ISDN, the rising edge of the clock is set (520) to correspond to the onset of the TCM-ISDN transmitting period. Similarly, the falling edge of the clock is set (530) to correspond to the onset of the inactive period, which, in the context of TCM-ISDN, would be the TCM-ISDN receiving period. The setting (520, 530) of the rising and falling edges of the clock results in a generation of a clock signal that is substantially synchronized to the periodicity of the cyclostationary disturbance. The generation of the clock signal now permits synchronization of the system with the cyclostationary disturbance. While, in some embodiments, the generated clock signal may correspond exactly with the TCM-ISDN clock signal, it should be appreciated that the generated clock signal need not correspond exactly to the TCM-ISDN clock signal. In this regard, the phase of the clock signals may be offset from each other due to timing delays, etc. Similarly, the frequency of the clock signals may differ from each other due to clock dividing functions, which are described below with reference to FIG. 6.

Continuing in FIG. 6, the generated clock signal may optionally be divided (620) to produce a higher frequency clock signal. Simlarly, while not shown, the frequency of the clock signal may also be reduced by known techniques. In any event, upon generating the clock signal, as shown in FIGS. 4 and 5, signals may be transmitted (630) during the active period, and received (640) during the inactive period.

FIG. 7 is an example timing diagram showing an example embodiment in which cyclostationary disturbances are generated by concurrent deployment of integrated services digital network (ISDN) and ADSL. The top line of the timing diagram shows the actual TCM-ISDN clock signal, while the remaining lines show the relationship between the TCM-ISDN clock signal and other TCM-ISDN and ADSL signals.

As shown in FIG. 7, the TCM-ISDN clock is defined by a fixed cyclostationary behavior. The transmission of ISDN signals from the ISDN central office (CO) are gated by the rising edge of the TCM-ISDN clock. In this regard, the ISDN CO beings transmission of the ISDN signal when the TCM-ISDN clock signal rises. The transmitted ISDN signal is received at the ISDN customer premises (CP) after a short delay, which is due to propagation of the signal across the communication line. When the TCM-ISDN clock signal falls, the ISDN-CP transmits ISDN signals, and the ISDN-CO receives the ISDN signals. In this regard, the ISDN-CP and ISDN-CO exhibit cyclostationary behavior. This cyclostationary behavior exhibits itself as cyclostationary disturbance in the ADSL system.

Thus, the disturbance on the ADSL-CO is greater during the ISDN-CO signal transmitting period than the ISDN-CO signal receiving period. Similarly, the disturbance on the ADSL-CO is reduced during the ISDN-CO signal receiving period. The behavior of the ADSL-CP displays converse behavior. In other words, when the ISDN-CO is transmitting, then the ADSL-CP exhibits a reduced disturbance.

As shown in FIG. 7, since the TCM-ISDN clock signal is recovered from the cyclostationary behavior of the ISDN signals, the ADSL data-loading scheme corresponds to the transmission and reception of ISDN signals. In this regard, the generated clock signal need not have an exact one-to-one correspondence with the actual TCM-ISDN clock but may, in some embodiments, have a delayed correspondence in which the phase of the rising edge and falling edge are slightly offset from the actual TCM-ISDN clock.

The processor 320 and the logic components 330, 332, 334, 340, 342, 344 described above may be implemented in hardware, software, firmware, or a combination thereof. In the preferred embodiment(s), the processor 320 and the logic components 330, 332, 334, 340, 342, 344 are implemented in hardware using any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc. In an alternative embodiment, the processor 320 and the logic components 330, 332, 334, 340, 342, 344 are implemented in software or firmware that is stored in a memory and that is executed by a suitable instruction execution system.

Any process descriptions or blocks in flow charts should be understood as representing modules, segments, or portions of code which include one or more executable instructions for implementing specific logical functions or steps in the process, and alternate implementations are included within the scope of the preferred embodiment of the present invention in which functions may be executed out of order from that shown or discussed, including substantially concurrently or in reverse order, depending on the functionality involved, as would be understood by those reasonably skilled in the art of the present invention. For example, while the steps of determining the active and inactive periods are shown in a specific order in FIG. 4, it should be appreciated that this order may be reversed or occur substantially concurrently without adversely affecting the scope of the invention. Similarly, while the steps of setting the rising and falling edges are shown in a particular order in FIG. 5, it should be appreciated that these steps may also occur substantially simultaneously or out of order without adversely affecting the scope of the invention. Likewise, the transmitting and receiving of signals in FIG. 6 need not occur in the order shown as long as the transmitting and receiving correspond to their respective active and inactive periods. Additionally, the aggregate of all the steps in FIGS. 4 through 6 may further be performed out of order without detriment to the scope of the invention. For example, the setting of the rising edge of the clock may occur immediately following the determination of the active period, rather than after the determination of the. inactive period. All such variations should, therefore, be seen as being within the scope of the invention.

Although exemplary embodiments have been shown and described, it will be clear to those of ordinary skill in the art that a number of changes, modifications, or alterations may be made, none of which depart from the spirit of the present invention. For example, while ISDN and DSL have been used to illustrate example embodiments of the invention, it should be appreciated by those skilled in the art that a clock signal may be generated by recovering any cyclostationary noise. In other words, in any system, if a disturbance exhibits itself as a periodic function, then that disturbance may be used to generate a clock signal. Additionally, while the generated clock signal is shown as having the same periodicity as the cyclostationary disturbance in the above-described embodiments, it should be appreciated that the generated clock signal may be further divided by clock-dividing techniques that are known in the art. Furthermore, while the logic components are shown as being within the encoder and gain scaler of the ATU, it should be appreciated that these logic components may be located in other portions of the DSL modem. In other words, as long as these components perform substantially the same function of determining the periodicity of the cyclostationary noise (e.g., the transmit and receive periods of TCM-ISDN signals) and setting the rising and falling edges of a clock signal, then these components may be located almost anywhere within the DSL modem. Also, while the embodiments of FIGS. 4 through 6 show that signals are transmitted from the system during the active disturbance period and received during the inactive disturbance period, it should be appreciated that the signals may be transmitted during the inactive disturbance period and received during the active disturbance period. These, and other such changes, modifications, and alterations, should therefore be seen as falling within the scope of the present invention.

What is claimed is:

1. In a communication environment that concurrently deploys an asymmetric Digital Subscriber Line (ADSL) service and a Time-Compression Multiplexed (TCM) Integrated Services Digital Network (ISDN) service on a single line, the TCM-ISDN service having a cyclical transmission protocol, the cyclical transmission protocol defining a transmitting period and a receiving period, a method for generating a clock signal, the method comprising:
receiving an ADSL signal from the single line, the ADSL signal having a first period that is correlated to the transmitting period of the TCM-ISDN service, the ADSL signal having a second period that is correlated to the receiving period for the TCM-ISDN service;
determining an onset of the transmitting period of the TCM-ISDN service from the received ADSL signal;
determining an onset of the receiving period of the TCM-ISDN service from the received ADSL signal;
setting a rising edge of a clock to correspond to the onset of the transmitting period; and
setting a falling edge of a clock to correspond to the onset of the receiving period.

2. In an environment exhibiting a cyclical disturbance, the cyclical disturbance having an active period and an inactive period, a method for generating a clock signal, the method comprising:
receiving a signal from a line, the signal comprising a first period that is correlated to the active period of the noise, the signal further comprising a second period that is correlated to the inactive period of the noise;
setting a rising edge of the clock signal to correspond to an onset of the active period of the noise; and
setting a falling edge of the clock signal to correspond to an onset of the inactive period of the noise.

3. The method of claim 2, further comprising:
dividing the generated clock signal to produce a higher frequency clock signal.

4. The method of claim 2, wherein receiving the signal from the line comprises:
receiving a signal correlated to transmission periods and reception periods of Integrated Services Digital Network (ISDN) signals on the line, the transmission period of ISDN signals corresponding to the active period of the noise, the reception period of the ISDN signals corresponding to the inactive period of the noise.

5. The method of claim 4, further comprising:
transmitting Digital Subscriber Line (DSL) signals on the line during the transmission period of the ISDN signals; and
receiving Digital Subscriber Line (DSL) signals on the line during the reception period of the ISDN signals.

6. The method of claim 4, further comprising:
receiving Digital Subscriber Line (DSL) signals on the line during the transmission period of the ISDN signals; and
transmitting Digital Subscriber Line (DSL) signals on the line during the reception period of the ISDN signals.

7. In a communication environment that concurrently deploys an asymmetric Digital Subscriber Line (ADSL) service and a Time-Compression Multiplexed (TCM) Integrated Services Digital Network (ISDN) service on a single line, the TCM-ISDN service having a cyclical transmission protocol, the cyclical transmission protocol defining a transmitting period and a receiving period, an apparatus for generating a clock signal, the apparatus comprising:
means for receiving an ADSL signal from the single line, the ADSL signal having a first period that is correlated to the transmitting period of the TCM-ISDN service, the ADSL signal having a second period that is correlated to the receiving period for the TCM-ISDN service;
means for determining an onset of the transmitting period of the TCM-ISDN service from the received ADSL signal;
means for determining an onset of the receiving period of the TCM-ISDN service from the received ADSL signal;
means for setting a rising edge of a clock to correspond to the onset of the transmitting period; and
means for setting a falling edge of a clock to correspond to the onset of the receiving period.

8. In an environment exhibiting a cyclical disturbance, the cyclical disturbance having an active period and an inactive period, a system for generating a clock signal, the system comprising:
a receiver adapted to receive a signal from a line, the signal comprising a first period that is correlated to the active period of the noise, the signal further comprising a second period that is correlated to the inactive period of the noise;
logic adapted to set a rising edge of the clock signal to correspond to an onset of the active period of the noise; and
logic adapted to set a falling edge of the clock signal to correspond to an onset of the inactive period of the noise.

9. The system of claim 8, further comprising:
a clock divider adapted to divide the generated clock signal.

10. The system of claim 8, wherein receiver is further adapted to receive a signal correlated to transmission periods and reception periods of Integrated Services Digital Network (ISDN) signals on the line, the transmission period of ISDN signals corresponding to the active period of the noise, the reception period of the ISDN signals corresponding to the inactive period of the noise.

11. The system of claim 10, further comprising:
a transmitter adapted to transmit Digital Subscriber Line (DSL) signals on the line during the transmission period of the ISDN signals.

12. The system of claim 10, wherein the receiver is further adapted to receive Digital Subscriber Line (DSL) signals on the line during the reception period of the ISDN signals.

13. The system of claim 10, further comprising:
a transmitter adapted to transmit Digital Subscriber Line (DSL) signals on the line during the reception period of the ISDN signals.

14. The system of claim 13, wherein the receiver is further adapted to receive Digital Subscriber Line (DSL) signals on the line during the transmission period of the ISDN signals.

15. In an environment exhibiting a cyclical disturbance, the cyclical disturbance having an active period and an inactive period, a system for generating a clock signal, the system comprising:
a receiver adapted to receive a signal from a line, the signal comprising a first period that is correlated to the active period of the noise, the signal further comprising a second period that is correlated to the inactive period of the noise;
logic adapted to determine an onset of the active period of the noise; and
logic adapted to determine an onset of the inactive period of the noise.

16. The system of claim 15, further comprising:
logic adapted to set a rising edge of the clock signal to correspond to the onset of the active period of the noise; and
logic adapted to set a falling edge of the clock signal to correspond to the onset of the inactive period of the noise.

17. The system of claim 16, further comprising:
a transmitter adapted to transmit signals on the line during the active period of the noise.

18. The system of claim 17, wherein the receiver is further adapted to receive signals on the line during the inactive period of the noise.

19. The system of claim 16, further comprising:
a transmitter adapted to transmit signals on the line during the inactive period of the noise.

20. The system of claim 19, wherein the receiver is further adapted to receive signals on the line during the active period of the noise.
